(19) United States
(12) Patent Application Publication
(10) Pub. No.: US 2006/0029126 A1
(43) Pub. Date: Feb. 9, 2006

(54) Apparatus and method for noise enhancement reduction in an adaptive equalizer

(75) Inventor: Chiao-Chih Chang, Taipei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Mediatek Inc.

(21) Appl. No.: 11/243,803

(22) Filed: Oct. 5, 2005

Related U.S. Application Data
(63) Continuation-in-part of application No. 11/102,944, filed on Apr. 11, 2005.
(60) Provisional application No. 60/562,485, filed on Apr. 15, 2004.

(51) Int. Cl. H03K 5/159

(52) U.S. Cl. 375/232

(57) ABSTRACT

A method for noise enhancement reduction in an adaptive equalizer comprising a plurality of filter tap cells having respective coefficients and tap data values. First, a step size is determined based on a norm value of an i^{th} parameter of an estimated channel response. The coefficient of the i^{th} filter tap cell is updated based on the step size, an error signal, and the tap data value of the i^{th} filter tap cell. The step size is determined by a piecewise function of the norm value of the i^{th} parameter. The piecewise function is a non-decreasing convex function or a non-decreasing stepwise function. An adaptive equalizer performing the described method is also provided.

The current application is supported by the provisional patent application No. 60/562,485 filed on Apr. 15, 2004, being a continuation-in-part of U.S. application Ser. No. 11/102,944 filed on Apr. 11, 2005, the entire disclosure of which being incorporated by reference herein in its entirety.

### BACKGROUND

The invention relates to adaptive equalizers, and in particular, to a method of enhancing noise reduction in an adaptive equalizer.

As is well known, in addition to being corrupted by noise, transmitted signals are also subject to channel distortion and distortion by multipath interference. Consequently, an adaptive equalizer is generally employed to compensate for these effects. FIG. 1 shows a conventional adaptive equalizer diagram. The adaptive equalizer 200 comprises a forward equalizer (FE) 202 and a decision feedback equalizer (DFE) 206. An input signal r(n) is provided to the FE 202, and the output therefrom added to the output from the DFE 206 in an adder 208 to generate the output signal y(n). The decision unit 203 generates a decision signal d(n) based on the output signal y(n), which acts as an estimate of the original transmitted value of the current output signal y(n) of the adaptive equalizer 200. The decision signal d(n) is then fed back to the DFE 206. As an example, the decision unit 203 may be a slicer slicing the output signal of the equalizer unit, with “slice” here referring to the process of taking the allowed symbol value nearest that of the output signal y(n).

The error estimator 207 generates an error signal e(n) based on the decision signal d(n) and the output signal y(n) Typically, the error signal e(n) is the difference between the decision signal d(n) and the output signal y(n). The coefficient updater 205 recursively updates the coefficients of the adaptive equalizer 200, including the coefficients of the FE 202 and the DFE 206 based on the error signal e(n), using the well-known Least Mean-Squared (LMS) algorithm. In a typical LMS algorithm, the coefficient vector C (n) of the adaptive equalizer 200 is updated using the following formula:
y(n)=C^{T}(n)X(n) (1)
e(n)=d(n)−y(n) (2)
C(n)=C(n−1)+μ·e(n)·X(n) (3)
where C(n)=[c₀(n), c₁(n), . . . , c_{K}(n)] is the coefficient vector of the adaptive equalizer 200 with K the number of coefficients of the adaptive equalizer 200, and wherein [c₀(n), c₁(n), . . . , c_{M-1}(n)] is the vector of the FE 202 with M being an integer less than K and [c_{M}(n), c_{M+1}(n), . . . , c_{K}(n)] is the vector of the DFE 206, and C^{T}(n) is the transpose of the coefficient vector C(n).

X(n)=[x₀(n), x₁(n), . . . , x_{K}(n)] is the tap data vector of the adaptive equalizer wherein [x₀(n), x₁(n), x_{M-1}(n)] is the tap data vector of the FE 202 and [x_{M}(n), x_{M+1}(n), . . . , x_{K}(n)] is the tap data vector of the DFE 206.

y(n) is the output signal of the adaptive equalizer 200, d(n) is the output of the decision unit 203, e(n) is the error signal, and μ is a step size.

In many applications, including digital television systems, the communication channel is corrupted by sparsely separated echoes. In such cases, the adaptive equalizer at receiver side, after adaptation settling time, has only a few non-zero valued equalizer coefficients, most of which are close to zero. Only the non-zero valued coefficients contribute to the equalization to perform channel echo cancellation.

FIG. 2 (a) shows a channel response having two echoes within a specific echo distance (measured by time). FIGS. 2(b) and (c) show the equalizer coefficients at different times. By employing the LMS algorithm, the equalizer coefficients are recursively updated to approximate the channel response of the transmission channel. As shown in FIGS. 2(b) and (c), two major coefficients, corresponding to the echoes of the transmission channel and revealing substantially non-zero values, are formed. The remaining equalizer coefficients are allminor coefficients, with values close to zero and random flicker as shown in FIGS. 2 (b) and (c). The variations of these minor coefficients generate excessive noise, causing inefficient convergence, referred to as noise enhancement. The situation will worsen if the number of equalizer coefficients is to be large enough to cover the maximum possible long-delayed echo. Therefore, it is desirable to reduce noise resulting from the variations of these minor coefficients such that the performance of the adaptive equalizer can be improved accordingly.

### SUMMARY

An embodiment of the invention provides a method for noise enhancement reduction in an adaptive equalizer comprising a plurality of filter tap cells having respective coefficients and tap data values. First, a step size is determined based on a norm value of an i^{th} parameter of an estimated channel response. The coefficient of the i^{th} filter tap cell is updated based on the step size, an error signal, and the tap data value of the i^{th} filter tap cell. The step size is a piecewise function of the norm value of the i^{th} parameter of the estimated channel response. The piecewise function can be a non-decreasing convex function or a non-decreasing stepwise function.

Another embodiment of the invention provides an adaptive equalizer performing the described method.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 is a conventional adaptive equalizer diagram;

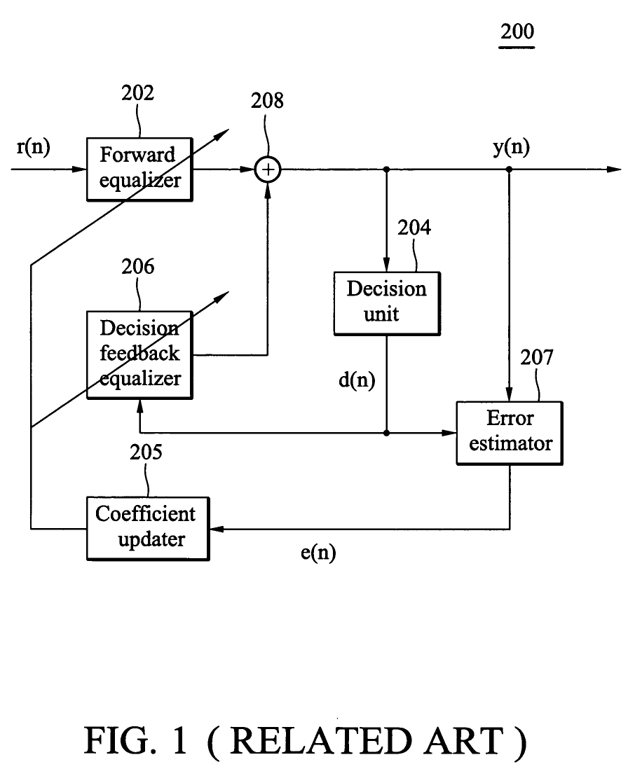

FIG. 2 shows channel response having two echoes within a specific echo distance (measured by time);

FIG. 3 is an adaptive equalizer diagram according to an embodiment of the invention;

FIG. 4a shows non-decreasing convex weighting w(|hᵢ(n)|) versus the norm value of the i^{th} channel parameter |hᵢ(n)|;

FIG. 4b shows non-decreasing stepwise weighting w(|hᵢ(n)|) versus the norm value of the i^{th} channel parameter |hᵢ(n)|;

FIG. 5 shows embodiment of the step size calculator 680;

FIG. 6 shows an i^{th} tap filter cell according to an alternative embodiment of the invention;

FIG. 7 shows another method of modifying the output signal of the filter tap cell 410 to reduce noise enhancement; and

FIG. 8 is a flowchart of the coefficient update.

### DETAILED DESCRIPTION

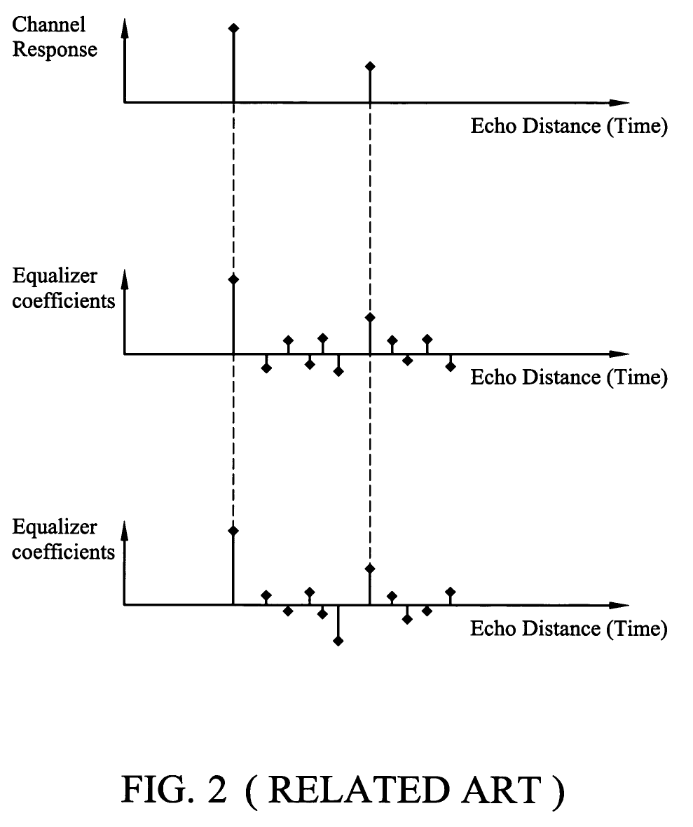

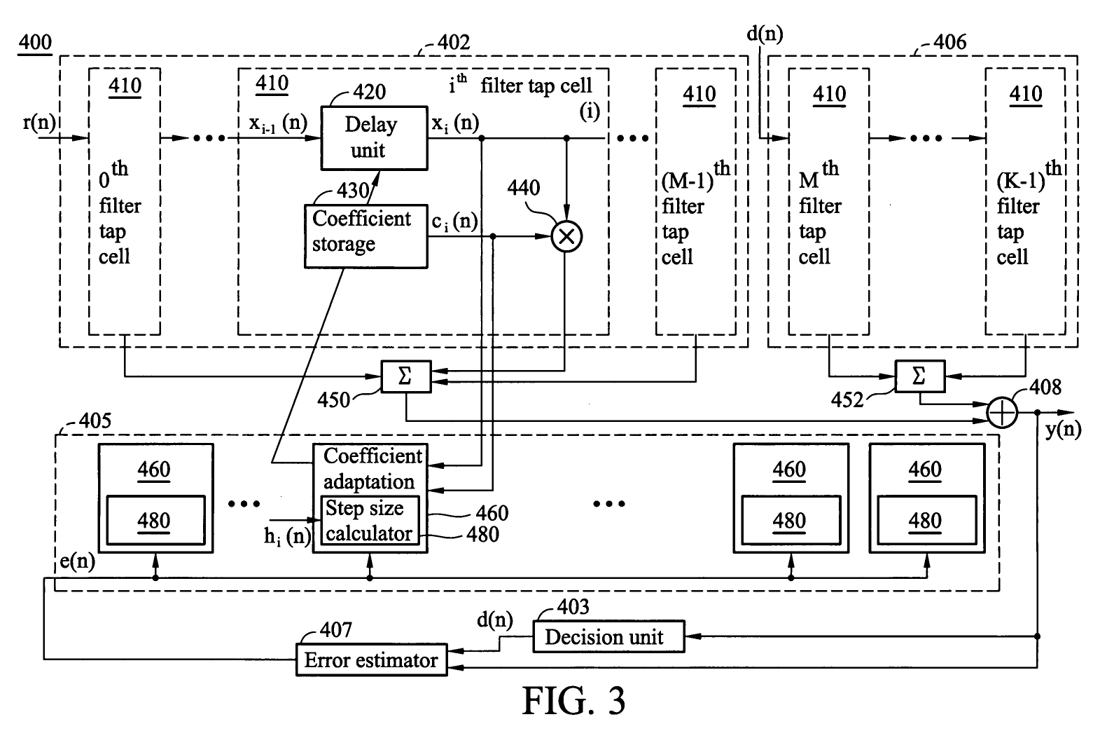

FIG. 3 shows an adaptive equalizer diagram according to an embodiment of the invention. The adaptive equalizer 400 comprises a forward equalizer (FE) 402 and a decision feedback equalizer (DFE) 406, an adder 408, a decision unit 403, an error estimator 407, and a coefficient updater 405. Other than the coefficient updater 405, the blocks are the same as those in FIG. 2, and detailed descriptions thereof are omitted. Both FE 402 and DFE 406 comprise a number of filter tap cells 410. In this case, the filter tap cells 410 are numbered from 0 to K−1, where K is an integer corresponding to the implementation of the adaptive equalizer 400, wherein the 0^{th}˜(M−1)^{th} filter tap cells belongs to FE 402 and M^{th}˜(K−1)^{th} belong to DFE 406. Note that the present invention can also be applied in an adaptive equalizer having only FE. Each filter tap cell 410 comprises a delay unit 420, a coefficient storage 430, and a multiplier 440. The delay unit 420 in the i^{th} tap cell receives and delays the data tap value xᵢ₋₁(n) of the (i−1)^{th} filter tap cell to obtain the data tap value xᵢ(n) for the present i^{th} filter tap cell. The coefficient storage 430 stores the coefficient cᵢ(n). Note that the input of the delay unit 420 in the first filter tap cell of FE 402 is the input signal r(n), and the input of the delay unit 420 in the first filter tap cell of DFE 406 is the decision signal d(n). The multiplier 440 in the i^{th} filter tap cell multiplies the tap data value xᵢ(n) by the coefficient cᵢ(n). The output of the multiplier 440 of each tap cell in FE is sent to a first integration unit 450 to generate the output of the FE. The first integration unit 450 sums the output of each multiplier 440 in FE 402 to generate an output signal of the FE 402. A second integration unit 452 sums the output of each multiplier 440 in DFE 406 to generate an output signal of the DFE 406.

The coefficient updater 405 comprises a plurality of adaptation units 460, each corresponding to a filter tap. The adaptation unit 460 corresponding to i^{th} tap cell calculates the coefficient cᵢ(n+1) for the next time point n+1 based on cᵢ(n), xᵢ(n), e(n) and hᵢ(n). The coefficient adaptation algorithm, is performed in the adaptation unit 460 in each filter tap cell 410 based on the algorithm:
cᵢ(n+1)=cᵢ(n)+e(n) xᵢ(n)·μ[|hᵢ(n)|] (4)
where:
cᵢ(n+1) is the coefficient of the i^{th} filter tap cell at time n+1;
cᵢ(n) is the coefficient of the i^{th} filter tap cell at time n;
e(n) is the error signal at time n;
xᵢ(n) is the tap data value of the i^{th} filter tap cell at time n;
hᵢ(n) is the i^{th} channel parameter of an estimated channel response h(n) at time n; and
μ[|hᵢ(n)|] denotes the step size that is a non-decreasing convex function of a norm value of the i^{th} channel parameter |hᵢ(n)|.

The step size calculator 480 computes the step size needed in the coefficient adaptation based on the i^{th} channel parameter hᵢ(n) according to the algorithm.
μ[|hᵢ(n)|]=μ₀·w(|hᵢ(n)|) (5)
where μ₀ is a preset constant and w(|hᵢ(n)|) is a weighting function having value in proportion to the norm value of the i^{th} channel parameter |hᵢ(n)|. According to the invention, μ[|hᵢ(n)|] is a non-decreasing convex function of a norm value of the i^{th} channel parameter hᵢ(n). Thus, the step size for updating the i^{th} coefficient is decrease d with amplitude of the corresponding i^{th} channel parameter. In other words, variations in the minor coefficients will be suppressed, reducing the noise enhancement.

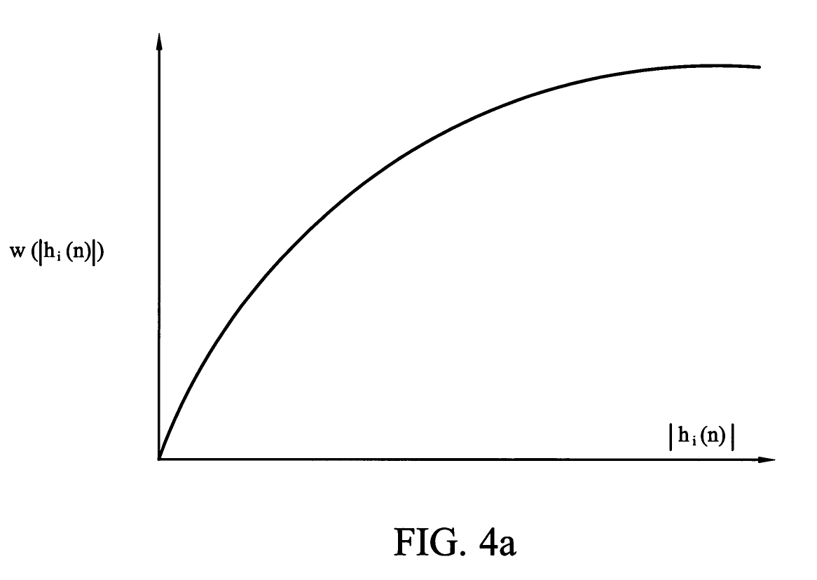

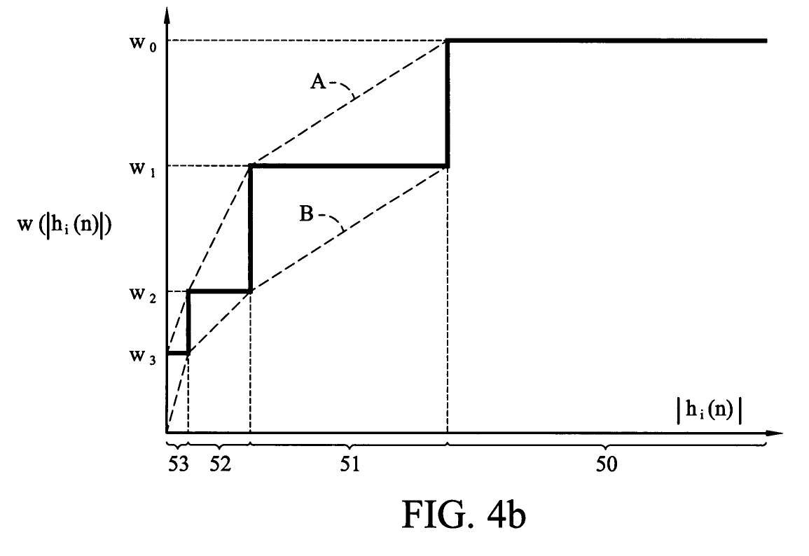

FIG. 4a shows the non-decreasing convex weighting function w(|hᵢ(n)|) versus the norm value f the i^{th} channel parameter |hᵢ(n)|. A convex function is a continuous function whose value at the midpoint of every interval in its domain exceed or equal to the average of its values at the ends of the interval. That is, a function f(x) is said to be convex on an interval [a, b] if f((x1+x2)/2)>=(f(x1)+f(x2))/2 for any points x1 and x2 in [a, b]. In this embodiment, the weighting function w(|hᵢ(n)|) can be preferably a logarithm function of the form:
a+b*log|hᵢ(n) (6)
Where a and b may be predetermined constants. The goal of the weighting function is to reduce coefficient jitters when no echo falls on that tap, and to maintain reasonable adapting abilities for tracking fast time-variant echoes.

FIG. 4b shows non-decreasing stepwise weighting w(|hᵢ(n)|) versus the norm value of the i^{th} channel parameter |hᵢ(n)|. In this example, the norm value of the iₜₕ channel parameter |hᵢ(n)| is divided into four regions 50, 51, 52, and 53. If |hᵢ(n)| falls in the region 50, w(|hᵢ(n) |)=w₀. If |hᵢ(n)| falls in the region 51, w(|hᵢ(n)|)=w₁. If |hᵢ(n)| falls in the region 52, w(|hᵢ(n)|)=w₂. If |hᵢ(n)| falls in the region 53, w(|hᵢ(n)|)=w₃. As shown in FIG. 4, w₃<w₂<w₁<w₀. In order to ease the practical implementation, it is preferred that wⱼ=w₀/2^{j}, j=1, 2, 3.

The stepwise function is just an example. In general, the weighting function generally can beta piecewise curve consisting of several curve segments satisfying that the curve A (or B) formed by connecting the starting (or ending) point of each curve segment is a non-decreasing convex curve. By this way, the invention can achieve the goal to reduce noise resulting from the variations of these minor EQ coefficients.

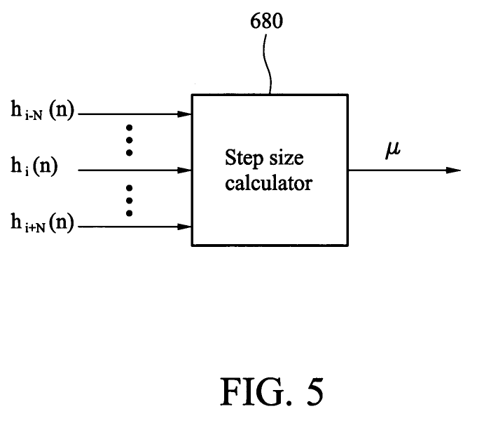

FIG. 5 shows another embodiment of the step size calculator 680. The step size calculator 680 determines a local maximum channel parameter having a local maximum norm value among the i^{th} parameter of the estimated channel response and those parameters adjacent to the i^{th} parameter, and calculates the step size by substituting the norm value of the local maximum channel parameter into the equation (5).

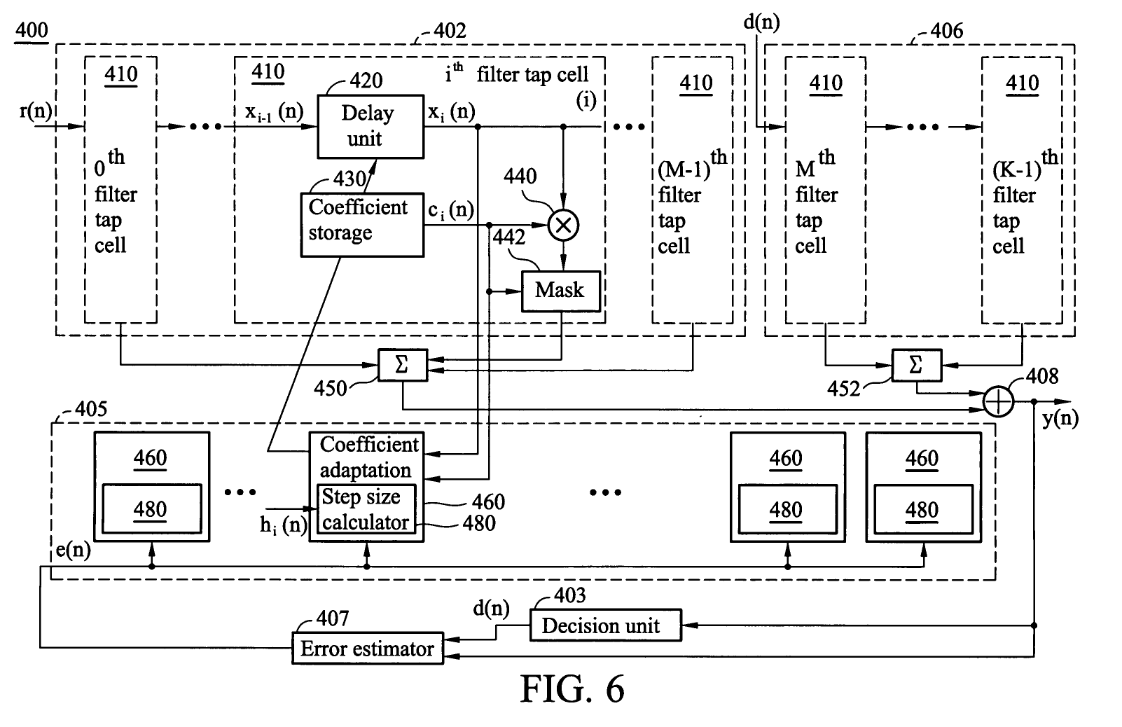

To further improve the performance of noise enhancement reduction, the generation of the output signal the of each filter tap cell 410 can be further modified. As shown in FIG. 6, the i^{th} tap filter cell further comprises a mask unit 442. The mask unit 442 sets the output signal of the i^{th} tap filter cell to zero if a norm value of the coefficient cᵢ(n) is less than a predetermined threshold. Otherwise, the mask unit 442 bypasses the output signal of the i^{th} tap filter. In this way, the variations of the minor coefficients, with norm values less than the predetermined threshold, are reduced to zero, reducing the noise enhancement.

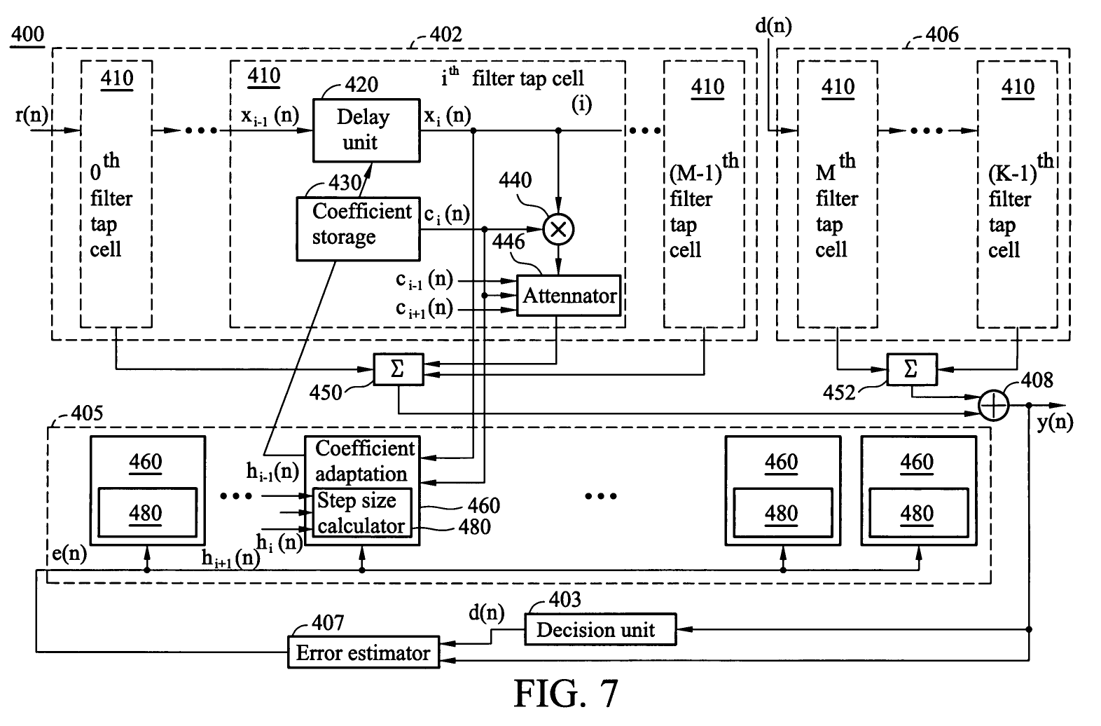

FIG. 7 shows another method of modifying the output signal of the filter tap cell 410. As shown in FIG. 7, the i^{th} tap filter cell further comprises an attenuator 446 attenuating the output signal of the i^{th} tap filter cell. If neither the corresponding coefficient nor the coefficient of the tap filter cell adjacent to the i^{th} tap filter cell have norm value greater than a predetermined threshold, the attenuator 446 modifies the output signal by multiplying the output signal with a preset factor. Otherwise, the attenuator 446 bypasses the output signal. In practical implementation, the preset factor can be ½^{N} where N is a positive integer, or even zero.

Channel response can be estimated by for example, via a conventional channel estimator or using the coefficients of tap filter cells. Norm value of the i^{th} parameter of the estimated channel response is referred to as the absolute value of the i^{th} parameter. Other types of norm value, e.g. the square of the absolute value, can also be applicable to the invention.

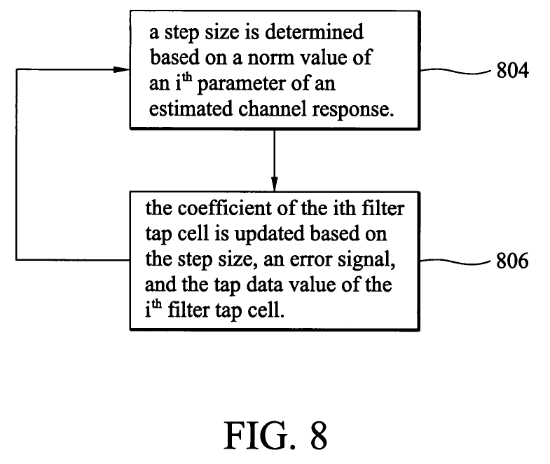

FIG. 8 is a flowchart of the coefficient update. In step 804, a step size is determined based on a norm value of an i^{th} parameter of an estimated channel response. In step 806, the coefficient of the i^{th} filter tap cell is updated based on the step size, an error signal, and the tap data value of the i^{th} filter tap cell. The step size is a non-decreasing convex function of the norm value of the i^{th} parameter of the estimated channel response. Step 804, is repeated to continue determination of the step size for next iteration, the procedure thereby looping to converge to a steady state after a period of time. The improved LMS algorithm reduces noise enhancement accordingly.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for noise enhancement reduction in an adaptive equalizer comprising a plurality of filter tap cells each storing a coefficient and a tap data value, the method comprising:
providing an estimated channel response comprising a plurality of parameters each corresponding to a filter cap cell;
determining a step size based on a norm value of the i^{th} parameter; and
updating the i^{th} coefficient based on the step size, an error signal, and the i^{th} tap data value; wherein the step size is determined by a piecewise function of the norm value of the i^{th} parameter.

2. The method as claimed in claim 1, wherein the piecewise function is a non-decreasing convex function segmented into a plurality of sections, with the beginning points of each section forming a non-decreasing convex curve, or the ending points of each section forming a non-decreasing convex curve.

3. The method as claimed in claim 1, wherein the piecewise function is a non-decreasing stepwise function.

4. The method as claimed in claim 1, wherein the channel response is estimated by the coefficients in the tap filter cells, and the i^{th} parameter of the estimated channel response is the i^{th} coefficient in the i^{th} tap filter cell.

5. The method as claimed in claim 1 wherein the norm value of the i^{th} parameter is referred to as the absolute value of the i^{th} parameter.

6. The method as claimed in claim 1, wherein step size determination comprises:
determining a local maximum channel parameter having a local maximum norm value among the i^{th} parameter and plural adjacent parameters; and
determining the step size based on the local maximum channel parameter.

7. The method as claimed in claim 1, wherein coefficient update comprises:
updating the i^{th} coefficient based on the formula:
cᵢ(n+1)=cᵢ(n)+e(n)xᵢ(n)μ[hᵢ(n)]
where:
cᵢ(n+1) is the coefficient of the i^{th} tap filter cell at time n+1;
cᵢ(n) is the coefficient of the i^{th} tap filter cell at time n;
e(n) is the error signal at time n;
xᵢ(n) is the tap data value of the i^{th} tap filter cell at time n;
hᵢ(n) is the i^{th} channel parameter of the estimated channel response at time n; and
μ[|hᵢ(n)|] denotes the step size, a non-decreasing convex function of a norm value of the i^{th} channel parameter |hᵢn)|.

8. The method as claimed in claim 1, further comprising generating an output signal of the i^{th} tap filter cell based on the corresponding coefficient and tap data value if a norm value of the corresponding coefficient exceeds a predetermined threshold, and otherwise, setting output signal of the i^{th} tap filter cell to zero.

9. The method as claimed in claim 1, further comprising:
generating an output signal of the i^{th} tap filter cell based on the corresponding coefficient and tap data value; and
attenuating the output signal by multiplying the output signal by a preset factor if neither the corresponding coefficient nor the coefficient of the tap filter cell adjacent to the i^{th} tap filter cell has norm value exceeding a predetermined threshold.

10. The method as claimed in claim 9, wherein the factor equals ½^{N}, where N is a positive integer.

11. The method as claimed in claim 9, wherein the factor equals zero.

12. An adaptive equalizer, comprising:
a plurality of filter tap cells each storing a coefficient and a tap data value;
a coefficient adaptation unit, updating the coefficient of an i^{th} filter tap cell based on a step size, an error signal, and the tap data value of the i^{th} filter tap cell, wherein the coefficient adaptation unit comprises a step size calculator determining the step size based on a norm value of an i^{th} parameter of an estimated channel response; wherein the step size is determined by a piecewise function of the norm value of the i^{th} parameter.

13. The adaptive equalizer as claimed in claim 12, wherein the piecewise function is a non-decreasing convex function segmented into a plurality of sections, with the beginning points of each section forming a non-decreasing convex curve, or the ending points of each section forming a non-decreasing convex curve.

14. The adaptive equalizer as claimed in claim 12, wherein the piecewise function is a non-decreasing stepwise function.

15. The adaptive equalizer as claimed in claim 12, wherein the channel response is estimated by the coefficients of tap filter cells, and the i^{th} parameter of the estimated channel response is the coefficient of the i^{th} tap filter cell.

16. The adaptive equalizer as claimed in claim 12, wherein the norm value of the i^{th} parameter of the estimated channel response is referred to as the absolute value of the parameter.

17. The adaptive equalizer as claimed in claim 12, wherein the step size calculator determines a local maximum channel parameter having a local maximum norm value among the i^{th} parameter and a plurality of parameters of the estimated channel response adjacent to the i^{th} parameter, and calculates the step size based on the local maximum channel parameter.

18. The adaptive equalizer as claimed in claim 12, wherein:
the coefficient adaptation unit updates the i^{th} coefficient based on:
cᵢ(n+1)=cᵢ(n)+e(n)r(n−i)μ[hᵢ(n)]
where:
cᵢ(n+1) is the i^{th} coefficient of the equalizer at time n+1;
cᵢ(n) is the i^{th} coefficient of the equalizer at time n;
e(n) is the error signal at time n;
r(n−i) is the i^{th} delayed version of the input signal at time n;
hᵢ(n) is the i^{th} channel parameter of the estimated channel response at time n; and
μ[hᵢ(n)] denotes the step size, a non-decreasing convex function of the i^{th} channel parameter hᵢ(n).

19. The adaptive equalizer as claimed in claim 12, wherein the i^{th} tap filter cell comprises a mask unit setting an output signal of the i^{th} tap filter cell to zero if a norm value of the
corresponding coefficient is less than a predetermined threshold.

20. The adaptive equalizer as claimed in claim 12, wherein the i^{th} tap filter cell comprises an attenuator attenuating the output signal of the i^{th} tap filter cell by multiplying the output signal by a preset factor if neither the corresponding coefficient nor the coefficient of the tap filter cell adjacent to the i^{th} tap filter cell having norm value exceeding a predetermined threshold.

21. The adaptive equalizer as claimed in claim 20, wherein the factor equals ½^{N} where N is a positive integer.

22. The method as claimed in claim 20, wherein the factor equals zero.
